(19) United States
(12) Patent Application Publication
(10) Pub. No.: US 2015/0292076 A1
(43) Pub. Date: Oct. 15, 2015

(54) METHOD AND DEVICE FOR PRODUCING SILVER-CONTAINING LAYER, SILVER-CONTAINING LAYER, AND SLIDING CONTACT MATERIAL USING SILVER-CONTAINING LAYER

(71) Applicant: TANAKA KIKINZOKU KOGYO K.K., Tokyo (JP)

(72) Inventors: Takao Asada, Hiratsuka-shi (JP); Junichi Takeuchi, Esashi-ku, Ohsu-shi, Iwate (JP); Ryuta Ido, Esashi-ku, Ohsu-shi, Iwate (JP); Atsushi Yumoto, Koto-ku (JP)

(73) Assignee: TANAKA KIKINZOKU KOGYO K.K., Tokyo (JP)

(21) Appl. No.: 14/443,507

(22) PCT Filed: Nov. 19, 2013
(86) PCT No.: PCT/JP2013/081211

§ 371 Date: May 18, 2015

(30) Foreign Application Priority Data
Nov. 19, 2012 (JP) 2012-253601

(51) Int. Cl. C23C 14/14; C22C 5/08; H01R 13/03; C22C 5/06; C23C 14/28; B32B 15/01

(52) U.S. Cl. CPC C23C 14/14; C23C 14/28; B32B 15/018; H01R 13/03; C22C 5/06; C22C 5/08

(57) ABSTRACT

In a cladding composite material obtained by coating the surface of a base material with an Ag-containing layer, it is difficult to make the size of fine Ag-containing particles which form the structure of the Ag-containing layer uniform in the thickness direction. A vaporization source (15) which contains Ag is irradiated by a high-energy laser beam 17 having a spot diameter for causing vaporization as fine particles which contain Ag from the vaporization source (15) which contains Ag, the fine particles which contain Ag are vaporized, and the fine particles which contain Ag which were obtained by vaporization are ejected as jet to a base material 33 under a high vacuum atmosphere to make than physically deposit on the base material 33 thereby Ag-containing layer is formed on the base material 33.

### TECHNICAL FIELD

The present invention relates to a method for producing an Ag-containing layer, an apparatus for the sane, an Ag-containing layer, and a sliding contact material using the sane. More particularly, it relates to a method for producing an Ag-containing layer which is used in a mechanical sliding portion of for example a DC small-sized motor or position sensor or other rotating device, an apparatus for the sane, an Ag-containing layer, and a sliding contact material using the sane.

### BACKGROUND ART

For example, studies have been intensively carried out for development of a new sliding contact material used in a mechanical sliding portion of a DC small-sized motor or position sensor or other rotating device and on its abrasion.

The known abrasions in a sliding contact material are roughly adhesive wear and abrasive wear.

Adhesive wear is caused by a softer metal being torn off and transferred to a harder metal due to melt bonding of metal materials constituting a sliding contact material.

Further, abrasive wear is caused in a case where materials which greatly differ in hardness slide against each other or a case where one of two soft materials contains hard particles.

As a sliding contact material used in a mechanical sliding portion of a rotating device, cladding composite material is used in which an AgCd alloy is bonded to a Cu or a CuSn alloy or other base material for use for example for a commutator of a DC small-sized motor.

An AgCd alloy has the problem of contamination of the environment by Cd, therefore a sliding contact material which can take the place of an AgCd alloy has been desired. A cladding composite material in which for example an AgZn alloy (see PLT 1), AgAl alloy (see PLT 2), AgNi alloy (see PLT 3), or Ag alloy matrix obtained by dispersing a Ta oxide (see PLT 4) was bonded to or buried in a Cu or a CuSn alloy or other base material has been developed.

Further, PLT 5 discloses use of an alloy comprised of Pd and Ag for use for example for a sliding contact material which is used in the mechanical sliding portion of a rotating device as a brush.

On the other hand, for use for example for a commutator (brush) of a DC small-sized motor, one comprised of a base material having a spring property on the surface of which an AgC sintered body is pressed bonded has been used. However, a cladding composite material obtained by cladding an AgPd alloy (50 wt % of Pd) or other precious mal layer on a base material as it can be produced while eliminating press bonding has been also used.

An AgPd alloy is excellent in hardness, abrasion resistance, wear resistance against sparks which are formed at the time of rectification, and stability of contact resistance, therefore is a material which is suitable for use as a brush.

An AgPd alloy layer is required to be kept down in the amount of materials used. There is known a method of forming the sane as a thin film by plating or a vapor deposition process in addition to rolling.

When using plating to coat an AgPd alloy on the surface of a base material, there are the problems that setting the conditions for plating is very difficult and the degree of freedom of composition of the AgPd alloy which can be formed is small. Further, if the thickness of the AgPd alloy layer is made great in order to increase the lifespan of the rotating device, the problems arise that an internal strain of the AgPd alloy layer becomes large, therefore cracking easily occurs at the time of film formation when the film is thickened and the degree of freedom of the film thickness is small.

When using the vapor deposition process to coat the surface of a base material with an AgPd alloy, the obtained AgPd alloy layer has a low adhesion with the base material, therefore there is the problem that the AgPd alloy is easily peeled off when it is used in a rotating device and made to slide, so commercial use is difficult. Further, in the vapor deposition process, during the film formation, the size of the fine particles of the AgPd alloy becomes large, therefore the size of fine particles of the AgPd alloy which form the structure of the AgPd alloy layer ends up becoming larger the further upward.

In the structure of the AgPd alloy layer which is formed according to the method described above, it is difficult to make the size of the fine particles of the AgPd alloy which form the structure uniform in the thickness direction, so coarse particles having a large size are contained in the structure of the AgPd alloy layer. When the coarse particles are peeled off at the time of abrasion of a sliding contact material such as a brush, they become caught at the contact parts of the sliding contact material and become the cause of poor contact at the contact parts and uneven lifespan of the rotating device.

### CITATIONS LIST

### Patent Literature

PLT 1: Japanese Patent Publication No. 8-260078A
PLT 2: Japanese Patent Publication No. 8-283885A
PLT 3: Japanese Patent Publication No. 2002-42584A
PLT 4: Japanese Patent Publication No. 2010-280971A
PLT 5: Japanese Patent Publication No. 03-71754B2
PLT 6: Japanese Patent Publication No. 2006-111921A

### SUMMARY OF INVENTION

### Technical Problem

In this way, for example, in a cladding composite material obtained by coating the surface of a base material with an AgPd alloy layer, it is difficult to make the size of fine particles of the AgPd alloy which form the structure of the AgPd alloy layer uniform in the thickness direction.

Other than the above-described AgPd alloy layer, for cladding composite materials obtained by coating the surfaces of base materials with an AgCu alloy layer and AgNi alloy layer or other Ag alloy layer and an Ag-nonmetal composite layer or other Ag-containing layer as well, the same situation arises as that for the AgPd alloy layer. It is difficult to make the size of fine particles of the Al alloy which form the structure of the Ag-containing layer or fine particles of the composite material of Ag and nonmetal which form the composite layer of Ag and nonmetal uniform in the thickness direction.

### Solution to Problem

The present inventors engaged in intensive studies and consequently discovered that (1) in order to cause Pg and Pd or other elements having different vapor pressures to vaporize while maintaining a constant composition, an AgPd alloy or other vaporization source which contains Ag should be irradiated by a high-energy laser beam minimizing a spot diameter to cause fine particles of AgPd alloy or other fine particles which contain Ag to vaporize and (2) then the fine particles of AgPd alloy which are generated or other fine particles which contain Ag should be made to be ejected as jet toward the base material in an extremely high vacuum atmosphere to make than physically deposit upon the base material.

Further, as a method of physical vapor deposition, for example, the physical vapor deposition apparatus of Japanese Patent No. 4828108 (Japanese Patent Publication No. 2006-111921A) described before as PLT 6 was improved so that it could be applied to the physical vapor deposition of fine particles which contain Ag.

As the light source of the high-energy laser beam, for example a YAG laser, CO₂ laser, excimer laser, or the like can be used. However, the spot diameters of these laser beams are made small so that the fine particles which contain Ag are generated with a particle size on the nanometer order.

A method for producing an Pg-containing layer of the present invention comprises a vaporization step of irradiating a vaporization source which contains Ag by a high-energy laser beam having a spot diameter for causing vaporization as fine particles which contain Ag from the vaporization source which contains Ag and vaporizing the fine particles which contain Ag and a vapor deposition step of ejecting the fine particles which contain Ag which were obtained by vaporization as jet to a base material under a high vacuum atmosphere to make them physically deposit on the base material.

In the method for producing the Ag-containing layer of the present invention described above, preferably, in the vaporization step a gas which contains the fine particles which contain Ag is ejected as jet on a gas stream from a nozzle and thereby physically deposit the fine particles which contain Ag on the base material.

In the method for producing the Ag-containing layer of the present invention described above, preferably, in the vaporization step the gas stream is a supersonic, transonic, or subsonic gas stream.

In the method for producing the Ag-containing layer of the present invention described above, preferably, in the vaporization step a laser beam of a fundamental harmonic of a YAG laser, CO₂ laser, or excimer laser or a laser beam having a small wavelength which is obtained by wavelength conversion of the fundamental harmonic is irradiated.

In the method for producing the Ag-containing layer of the present invention described above, preferably, the base material is Cu or a Cu alloy.

In the method for producing the Ag-containing layer of the present invention described above, preferably, the fine particles which contain Ag are AgPd fine particles, and an AgPd alloy layer is produced as the Ag-containing layer.

In the method for producing the Ag-containing layer of the present invention described above, preferably, the fine particles which contain Ag are AgCu fine particles, and an AgCu alloy layer is produced as the Ag-containing layer.

In the method for producing the Ag-containing layer of the present invention described above, preferably, the fine particles which contain Ag are AgNi fine particles, and an AgNi alloy layer is produced as the Ag-containing layer.

In the method for producing the Ag-containing layer of the present invention described above, preferably, the fine particles which contain Ag are Ag-nonmetal composite fine particles, and an Ag-nonmetal composite layer is produced as the Ag-containing layer.

An apparatus for producing an Ag-containing layer of the present invention comprises a laser source for irradiating a high-energy laser beam having a spot diameter for causing vaporization from a vaporization source which contains Ag as fine particles which contain Ag, a vaporization chamber for irradiating the vaporization source which contains Ag by the laser beam and vaporizing fine particles which contain Ag, a transfer tube for transferring the fine particles which contain Ag, and a film-forming chamber for ejecting the fine particles as jet which contain Ag from a nozzle arranged on a front end of the transfer tube to the base material under a high vacuum atmosphere and making than physically deposit on the base material.

An Ag-containing layer of the present invention is formed by irradiating a vaporization source which contains Ag by a high-energy laser beam having a spot diameter for causing vaporization from the vaporization source which contains Ag as fine particles which contain Ag, and ejecting the fine particles which contain Ag which were obtained by vaporization by irradiating as jet to a base material under a high vacuum atmosphere to make than physically deposit on the base material.

The Ag-containing layer of the present invention is formed by depositing 1 to 200 nm size fine particles which contain Ag with a uniform size in the thickness direction on a base material.

A sliding contact material of the present invention comprises a base material and an Ag-containing layer which is formed by irradiating a vaporization source which contains Ag by a high-energy laser beam having a spot diameter for causing vaporization from the vaporization source which contains Ag as fine particles which contain Ag, and ejecting the fine particles which contain Ag which were obtained by vaporization by irradiating as jet to a base material under a high vacuum atmosphere to make them physically deposit on the base material.

A sliding contact material of the present invention comprises a base material and an Ag-containing layer which is formed by depositing 1 to 200 nm size fine particles which contain Ag with a uniform size in the thickness direction on the base material.

### Advantageous Effects of Invention

According to the present invention, for example, the size of the fine particles which contain Ag which form the structure of the Ag-containing layer of the cladding composite material etc. which is obtained by coating the surface of the base material with the Ag-containing layer can be made uniform in the thickness direction.

### BRIEF DESCRIPTION OF DRAWINGS

FIG. 1 is a schematic cross-sectional view of a sliding contact material according to a first embodiment of the present invention.

FIG. 2 is a schematic diagram of the constitution of a physical vapor deposition apparatus used in a method of producing the sliding contact material according to the first Embodiment of the present invention.

FIG. 3 is a schematic diagram showing a manufacturing process of the method of producing the sliding contact material according to the first embodiment of the present invention.

FIG. 4 is a schematic diagram of the constitution of a physical vapor deposition apparatus used in a method of producing a sliding contact material according to a second Embodiment of the present invention

FIGS. 5A to 5D are electron micrographs according to a first example of the present invention.

FIGS. 6A to 6D are electron micrographs according to the first example of the present invention.

FIG. 7A and FIG. 7B are electron micrographs according to the first example of the present invention.

FIGS. 8A to 8C are electron micrographs according to the first example of the present invention.

FIG. 9 is a schematic diagram of a sliding test device.

FIG. 10 is an electron micrograph according to Example 3b in the second example of the present invention.

FIG. 11 is an electron micrograph of the surface of Comparative Example 1b in the second example of the present invention.

FIG. 12 is an electron micrograph according to Example 3c in a third example of the present invention.

FIG. 13 is an electron micrograph of the surface of Comparative Example 1c in the third example of the present invention.

FIG. 14 is an electron micrograph according to Example 3d in a fourth example of the present invention.

FIG. 15 is an electron micrograph according to Example 7d in the fourth example of the present invention.

FIG. 16 is an electron micrograph of the surface of Comparative Example 1d in the fourth example of the present invention.

FIG. 17 is an electron micrograph of the surface of Comparative Example 2d in the fourth example of the present invention.

### DESCRIPTION OF EMBODIMENTS

Below, embodiments of the present invention of a method for producing an AgPd alloy layer, AgCu alloy layer, AgNi alloy layer, or other Ag-containing layer and an Ag-nonmetal composite layer or other Ag-containing layer, an apparatus for the sane, and an AgPd alloy layer, AgCu alloy layer, AgNi alloy layer, or other Ag-containing layer and Ag-nonmetal composite layer or other Ag-containing layer will be explained with reference to the drawings.

In particular, as one application of the present invention using the method of producing an AgPd alloy layer, AgCu alloy layer, AgNi alloy layer, or other Ag-containing layer and Ag-nonmetal composite layer or other Ag-containing layer, a method for producing a sliding contact material will be explained.

### First Embodiment

### Constitution of Sliding Contact Material (AgPd Alloy Layer)

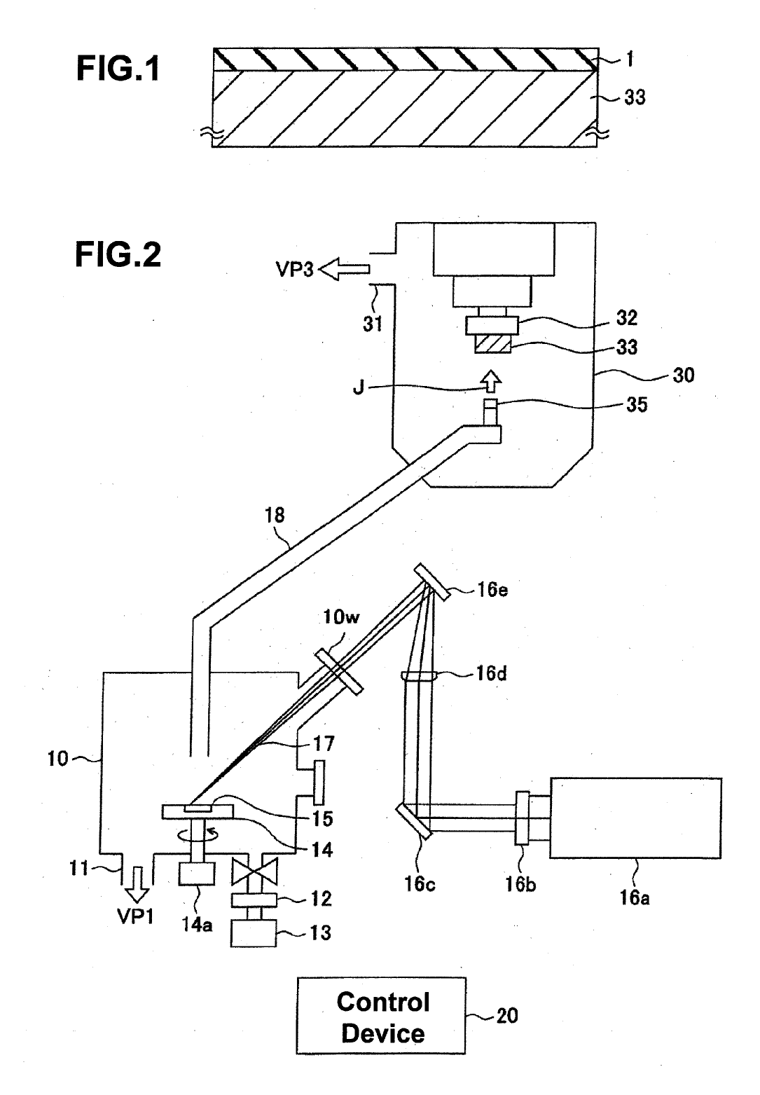

FIG. 1 is a schematic cross-sectional view of a sliding contact material according to an embodiment of the present invention.

In the sliding contact material of the present embodiment, an AgPd alloy layer 1 is formed as an Ag-containing layer on a base material 33.

The base material 33 is for example made of Cu or CuSn, CuSnNi, or other Cu alloy and has a spring property which is suitable when used as a sliding contact material.

The AgPd alloy layer 1 in the present embodiment is formed by irradiating the AgPd alloy by a high-energy laser beam having a spot diameter for causing vaporization from an AgPd alloy as fine particles of AgPd alloy and ejecting the fine particles of AgPd alloy which were obtained by vaporization by irradiating to the base material 33 under a high vacuum atmosphere to make then physically deposit on the base material 33.

In the AgPd alloy layer 1, for example Pd can be suitably adjusted within a range of 0 to 100 wt %, therefore the degree of freedom of composition of the AgPd alloy which can be formed is large. The invention can be applied also to Pg alone with Pd: 0 wt % or to Pd alone with Pd: 100 wt %.

Further, the film thickness of the AgPd alloy layer 1 is for example 0.05 to 22 μm, preferably 1 to 10 μm.

The AgPd alloy layer of the sliding contact material in the present embodiment is obtained by depositing fine particles of AgPd alloy having for example 1 to 200 nm size. It is formed by depositing fine particles of AgPd alloy with a uniform size in the thickness direction of the AgPd alloy layer 1.

Alternatively, the AgPd alloy layer of the sliding contact material in the present embodiment is a layer obtained by for example depositing fine particles of AgPd alloy obtained as secondary particles by aggregation of a plurality of primary particles of AgPd alloy having 1 to 20 nm size. It is formed by depositing the fine particles of AgPd alloy with a uniform size in the thickness direction of the AgPd alloy layer.

The base material 33 on which the above AgPd alloy layer 1 is formed is worked to for example a brush shape and can be applied to a sliding contact material which is used in a mechanical sliding portion of a DC small-sized motor, position sensor, or other rotating device as a brush.

In particular, the size of the fine particles of AgPd alloy which form the structure of the AgPd alloy layer becomes uniform in the thickness direction. Therefore, even when peeling of fine particles of AgPd alloy occurs at the time of sliding, a new fine particle surface is formed on the surface after peeling so the problem of poor contact can be suppressed, so this is suitable for a sliding contact material. In particular, this is suitable for small current and microcontact sliding contact parts, therefore can be preferably used for a sliding contact material which is used in a mechanical sliding portion of a DC small-sized motor, position sensor, or other rotating device as a brush.

[Production Method and Production Apparatus of Sliding Contact Material (AgPd Alloy Layer)]

Next, a method of producing a sliding contact material (AgPd alloy layer) according to the present embodiment will be explained.

The method of producing the sliding contact material according to the present embodiment first irradiates the AgPd alloy by a high-energy laser beam having a spot diameter for causing vaporization from the AgPd alloy as fine particles of AgPd alloy and vaporizes the fine particles which contain Ag.

Next, it ejects the fine particles of AgPd alloy which are obtained by vaporization as jet to the base material under a high vacuum atmosphere to make them physically deposited on the base material.

The method of producing the sliding contact material (AgPd alloy layer) described above is carried out by the physical vapor deposition process using the following physical vapor deposition apparatus.

FIG. 2 is a schematic diagram of the constitution of a production apparatus of the sliding contact material (AgPd alloy layer) according to the present embodiment as constituted by a physical vapor deposition apparatus.

The physical vapor deposition apparatus is for example provided with a vaporization chanter 10 and with a vacuum chamber for film formation constituted by a film-forming chamber 30.

The vaporization chamber 10 is for example provided with an exhaust pipe 11 which is connected to a vacuum pump VP1. The interior of the vaporization chamber 10 is evacuated by operation of the vacuum pump VP1, for example, is evacuated to a vacuum atmosphere of about 10⁻⁶ Torr. Preferably, the gas is replaced, then the chamber is further evacuated.

Further, a gas supply source 13 which is provided at the vaporization chamber 10 through a mass flow control 12 is, according to need, supplies He or N₂ or another inert atmospheric gas to the vaporization chamber 10 with a predetermined flow rate. Note that, at the time of film formation, the vaporization chamber 10 is made the air atmosphere or reduced-pressure atmosphere.

In the vaporization chamber 10, for example, a table 14 is provided which is connected to a rotary motor 14a and is constituted so that it can be driven to rotate, and a vaporization source 15 comprised of an AgPd alloy is arranged on this.

The vaporization chamber 10 is for example provided with a laser source 16a and an optical system which guides a laser beam 17 which is Emitted from the laser source 16a. The optical system is for example constituted by an aperture 16b, mirror 16c, lens 16d, mirror 16e, and so on. The optical system may be given configured so that mirrors, lenses, etc. other than those described above are further used as well. The laser beam 17 from the laser source 16a is made to converge by the lens, is guided from a light irradiation window 10w made of quartz or the like which is provided in the vaporization chamber 10 to the inside of the vaporization chamber 10, and irradiates the vaporization source 15, so the vaporization source 15 is heated.

For example, the drive operation of the rotary motor 14a and the drive operation of the laser source 16a are controlled as a whole by a control device 20.

The vaporization source 15 is heated by the laser beam to vaporize whereby fine particles of AgPd alloy (hereinafter, also referred to as AgPd alloy nanoparticles) having a size on the nanometer order are generated from atoms which are obtained by vaporization from the vaporization source 15.

The generated AgPd alloy nanoparticles are transferred together with the atmospheric gas in the vaporization chamber 10 through a transfer tube 18 to the film-forming chamber 30.

As the laser source 16a, for example, and Nd:YAG laser using a Q-switch, CO₂ laser, excimer laser, or the like can be suitably used.

For example, a laser beam of a fundamental harmonic (1064 nm) of a Nd:YAG laser, a fundamental harmonic (about 10 μm) of a CO₂ laser, or a fundamental harmonic of an excimer laser (308 nm in a case of XeCl excimer laser) or a laser beam having a short wavelength which is obtained by converting the wavelength of the fundamental harmonic such as to a second order harmonic or third order harmonic is used.

For example, the laser beam 17 is converged to a predetermined spot diameter by the lens and irradiates the vaporization source 15 of AgPd alloy, thereby vaporizing the fine particles of AgPd alloy having a size of 1 to 200 nm.

The film-forming chamber 30 is provided with an exhaust pipe 31 which is connected to a vacuum pump VP3. The interior of the film-forming chamber 30 is evacuated by operation of the vacuum pump VP3 and is made a vacuum atmosphere of for example about 10⁻⁶ Torr.

In the film-forming chamber 30, for example, a stage 32 is provided. At this stage 32, a base material 33 on which the film is to be formed is fixed.

For example, on the front end of the transfer tube 18 from the vaporization chamber 10, a nozzle 35 is provided which ejects the nanoparticles obtained in the vaporization chamber 10 together with the atmospheric gas into the film-forming chamber 30.

Between the vaporization chamber 10 and the film-forming chamber 30 described above, a flow of gas is generated due to a pressure difference. The above AgPd alloy nanoparticles are transferred together with the atmospheric gas through the transfer tube to the film-forming chamber 30 and are ejected from the nozzle 35 as a gas stream J toward the base material 33 inside the film-forming chamber 30.

The nozzle 35 is designed in accordance with the type and composition of the gas and the exhaust capacity of the film-forming chamber based on one-dimensional or two-dimensional compressible fluid dynamics theory. This is connected to the front end of the transfer tube 18 or formed integrally with the front end part of the transfer tube 18.

Specifically, this is a reduced-enlarged tube in which the internal diameter of the nozzle varies. This can raise the gas stream induced by the differential pressure between the vaporization chamber and the film-forming Climber up to a supersonic speed, for example, 1.2 or more in terms of Mach number.

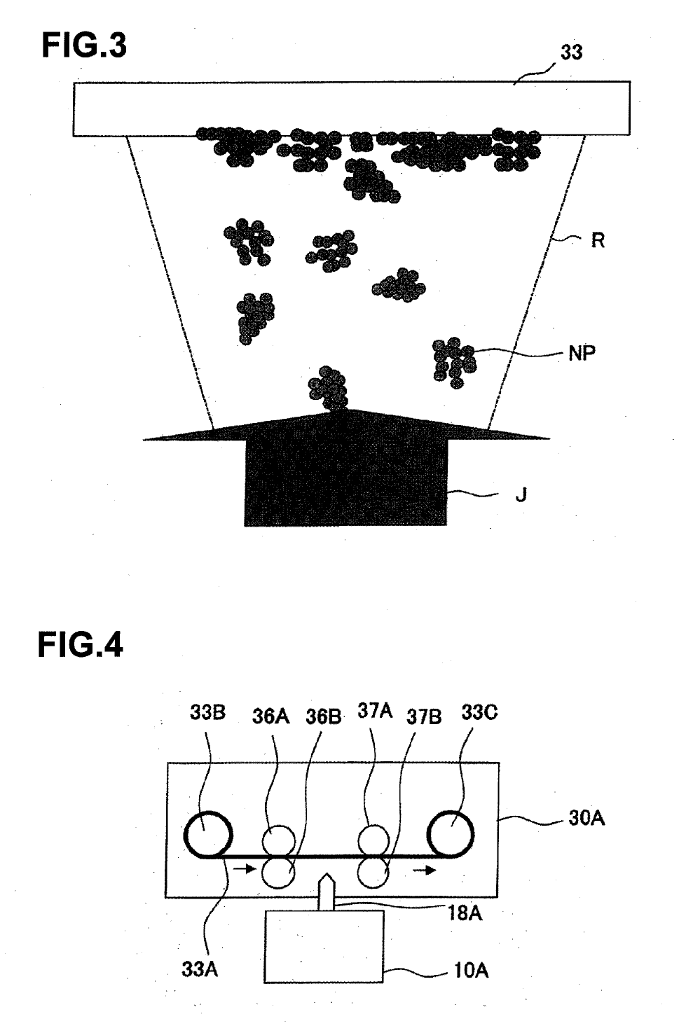

FIG. 3 is a schematic diagram showing the manufacturing process of the method of producing the sliding contact material (AgPd alloy layer) according to the present embodiment.

By the nozzle 35 having the above constitution, the gas stream which contains the AgPd alloy nanoparticles NP and the atmospheric gas is accelerated up to a supersonic speed, and the AgPd alloy nanoparticles NP are placed on the gas stream J to be ejected toward the base material 33 inside the film-forming chamber 30, then are physically deposited on the base material 33 within an ejection range R of the gas stream J, thereby forming the AgPd alloy layer.

In the present embodiment, by heating by using the laser beam, it becomes possible to give a large energy that contributes to the vaporization of the vaporization source. The vaporization source can be locally heated in accordance with the spot of the laser beam. The locally heated portion is formed into nanoparticles of AgPd alloy with the composition maintained as it is.

In a constitution heating and melting the entire vaporization source, the nanoparticles are generated in accordance with the vapor pressure of the element contained in the vaporization source. Therefore, according to some conditions, there sometimes arises the inconvenience that the composition etc. fluctuate during the film formation.

In the present embodiment, the locally heated portion of the vaporization source is formed into nanoparticles of AgPd alloy while maintaining its composition as it is, therefore the inconvenience of the composition fluctuating during the film formation can be suppressed.

Further, by changing the composition of the vaporization source comprised of the AgPd alloy, the composition of the AgPd alloy layer which is formed on the base material can be easily changed. For example, by changing the composition of the vaporization source, it is possible to suitably adjust the composition of the AgPd alloy layer 1 within a range of Pd of 0 to 100 wt %, therefore the degree of freedom of the composition of the AgPd alloy which can be formed is large.

The film thickness of the AgPd alloy layer 1 which is formed in the present embodiment is for example 0.05 to 22 μm, preferably 1 to 10 μm.

According to the method of producing the sliding contact material of the present embodiment, there are the following advantages: Even if the film thickness of the AgPd alloy layer is increased up to for example about 5 to 22 μm, the internal strain is small, cracking at the time of the film formation can be suppressed, and the degree of freedom of the film thickness is large.

The AgPd alloy layer which is formed in the method of producing the sliding contact material of the present embodiment has a high adhesion with the base material. Therefore, even when it is made to slide when used in a rotating device, peeling of the AgPd alloy layer can be suppressed.

In the method of producing the sliding contact material of the present embodiment, for example, the AgPd alloy layer can be formed by depositing fine particles of AgPd alloy having a size of 1 to 200 nm with a uniform size in the thickness direction of the AgPd alloy layer.

Alternatively, for example, the AgPd alloy layer can be formed by depositing fine particles of AgPd alloy which become secondary particles by aggregation of a plurality of primary particles of AgPd alloy having a size of 1 to 200 nm with a uniform size in the thickness direction of the AgPd alloy layer.

In the structure of the AgPd alloy layer formed according to the conventional method, it is difficult to make the size of the fine particles of AgPd alloy which form the structure uniform in the thickness direction, so coarse particles having a large size were contained in the structure of the AgPd alloy layer.

By the method of producing the sliding contact material in the present embodiment, the cladding composite material obtained by coating the surface of the base material with the AgPd alloy layer forming the sliding contact material can be formed so that the size of the fine particles of AgPd alloy which form the structure of the AgPd alloy layer becomes uniform in the thickness direction.

Accordingly, peeling of coarse particles at the time of abrasion of the sliding contact material is prevented, therefore poor contact in the contact parts and variation of lifespan as the rotating device can be suppressed.

In the above description, an explanation was given of acceleration of the gas stream which contains the AgPd alloy nanoparticles up to a supersonic speed by the nozzle 35. The nozzle 35 may be a reduced tube where the internal diameter of the nozzle is varied or for example a reduced-enlarged tube giving a subsonic speed of 0.75 or less in terms of Mach number at the outlet of the nozzle or a transonic speed of about 0.75 to 1.25 in terms of Mach number at the sane position and may be configured so that it can raise the gas stream induced due to the differential pressure between the vaporization chamber and the film-forming chamber up to for example a subsonic speed of 0.75 or less in terms of Mach number or a transonic speed of about 0.75 to 1.25 in terms of Mach number.

By the nozzle 35 having the above constitution, the gas stream which contains the nanoparticles and atmospheric gas is accelerated up to a subsonic or transonic speed, and the nanoparticles are placed on the gas stream J to be ejected toward the base material 33 inside the film-forming chamber 30 and be physically deposited on the base material 33, thereby forming the AgPd alloy layer.

For example, the vaporization chamber 10 is evacuated to 5 kPa (38 Torr) to 90 kPa (680 Torr), and the film-forming chamber 30 is evacuated to 0.01 kPa (0.08 Torr) to 5 kPa (38 Torr).

In the case of a constitution accelerating the gas stream which contains the above AgPd alloy nanoparticles and atmospheric gas up to a subsonic or transonic speed, since the velocity of the gas stream is subsonic or transonic, the degree of freedom of design of the nozzle used becomes high, the design itself and fabrication become easy, and thus the costs of the physical vapor deposition apparatus can be reduced.

Further, in the case Where the gas stream is accelerated up to a subsonic or transonic speed, the influence of a shock wave which is generated in the gas stream in the supersonic region can be eliminated or can be made very small.

Further, when the velocity of the gas stream is made subsonic or transonic, the effects of the following (1) to (3) can be further acquired.

(1) The influence of the shock wave when the nanoparticles strike the base material on which the film is to be formed is nonexistent or is very small.

(2) The pressure difference between the vaporization chamber and the film-forming chamber can be made small, therefore it becomes possible to make the pup performance of the film-forming chamber low. Due to this, it is possible to reduce the costs of the physical vapor deposition apparatus. Further, the pressure of the vaporization chamber can be made low, the flow rate of helium can be reduced, and it is possible to reduce the cost by this.

(3) The degree of freedom of the distance between the nozzle provided in the film-forming chamber and the base material on which the film is to be formed increases.

### Second Embodiment

FIG. 4 is a schematic diagram of the constitution of a physical vapor deposition apparatus which is used in the method of producing the sliding contact material (AgPd alloy layer) according to the present embodiment.

This is a physical vapor deposition apparatus of a system which drives a plate-shaped base material rolled in one direction in this one direction. In a vaporization chamber 30A, a base material 33A is conveyed from an unwinding roll to a winding roll 33C by conveyor rolls 36A, 36B, 37A, and 37B.

In FIG. 4, a vaporization chamber 10A is provided. Although illustration is omitted, this has the same constitution as that of the vaporization chamber 10 shown in FIG. 2 according to the first embodiment.

In the vaporization chamber 10A, the AgPd alloy nanoparticles are generated in the same way as the first embodiment.

A transfer tube 18A is provided between the vaporization chamber 10A and the film-forming chamber 30A, and a not shown nozzle is provided on the front end of the transfer tube 18A.

Between the vaporization chamber 10A and the film-forming chamber 30A described above, a flow of gas is generated due to a pressure difference. The AgPd alloy nanoparticles which are obtained in the vaporization chamber 10A are transferred together with the atmospheric gas through the transfer tube 18A to the film-forming chamber 30A and are ejected as the gas stream from the nozzle toward the base material 33A inside the film-forming chamber 30A to be physically deposited on the base material 33A.

In FIG. 4, a region in which the base material 33A is held flat between the conveyor rolls 36A and 36B and the conveyor rolls 37A and 37B becomes the physical vapor deposition region.

In the present embodiment, the AgPd alloy layer can be continuously formed on the plate-shaped base material which is rolled in one direction.

Here, in the vaporization chamber 10A, the laser beam is used in the same way as the first embodiment, and an AgPd alloy layer in accordance with the composition of the vaporization source can be formed. Therefore, in any film-forming region of the plate-shaped base material which is rolled in one direction, a constant AgPd alloy composition can be maintained.

According to the method of producing the sliding contact material in the present embodiment, the cladding composite material which is obtained by coating the surface of the base material with the AgPd alloy layer forming the sliding contact material can be formed so that the size of the fine particles of the AgPd alloy which form the structure of the AgPd alloy layer becomes uniform in the thickness direction.

Accordingly, peeling of coarse particles at the time of abrasion of the sliding contact material is prevented, contact resistance at the time of sliding of the sliding contact material is good, the abrasion loss is small, and poor contact in the contact parts and variation of lifespan as the rotating device can be suppressed.

Other than the effects described above, effects sane as those by the method of producing the sliding contact material according to the first embodiment can be obtained.

### First Example

According to the method of producing the sliding contact material according to the first embodiment, AgPd alloy layers having compositions shown in Table 1 were formed with a film thickness of 2 μm on base materials comprised of CuSn alloy to thereby prepare Examples 1a to 6a.

Further, a cladding method according to the prior art was used to form an AgPd alloy layer on a substrate to a film thickness of 2 μm to prepare Comparative Example 1a.

TABLE 1

| | | | Dimension of | | | |
|---|---|---|---|---|---|---|
| | | | crystal grains | | | |
| | | | of | Presence | Sliding test | |
| | Composition | | cross-sectional | of | Contact | Abra- |
| | (wt %) | | structure | coarse | resis- | sion |
| | Ag | Pd | (nm) | particles | tance | loss |
| Example 1a | 50 | 50 | 20 | No | Good | Good |
| Example 2a | 50 | 50 | 40 | No | Good | Good |
| Example 3a | 50 | 50 | 100 | No | Good | Good |
| Example 4a | 50 | 50 | 170 | No | Good | Good |
| Example 5a | 90 | 10 | 120 | No | Good | Good |
| Example 6a | 10 | 90 | 80 | No | Good | Good |
| Comparative | 50 | 50 | 5000 | Yes | Poor | Fair |
| Example 1a | | | | | | |

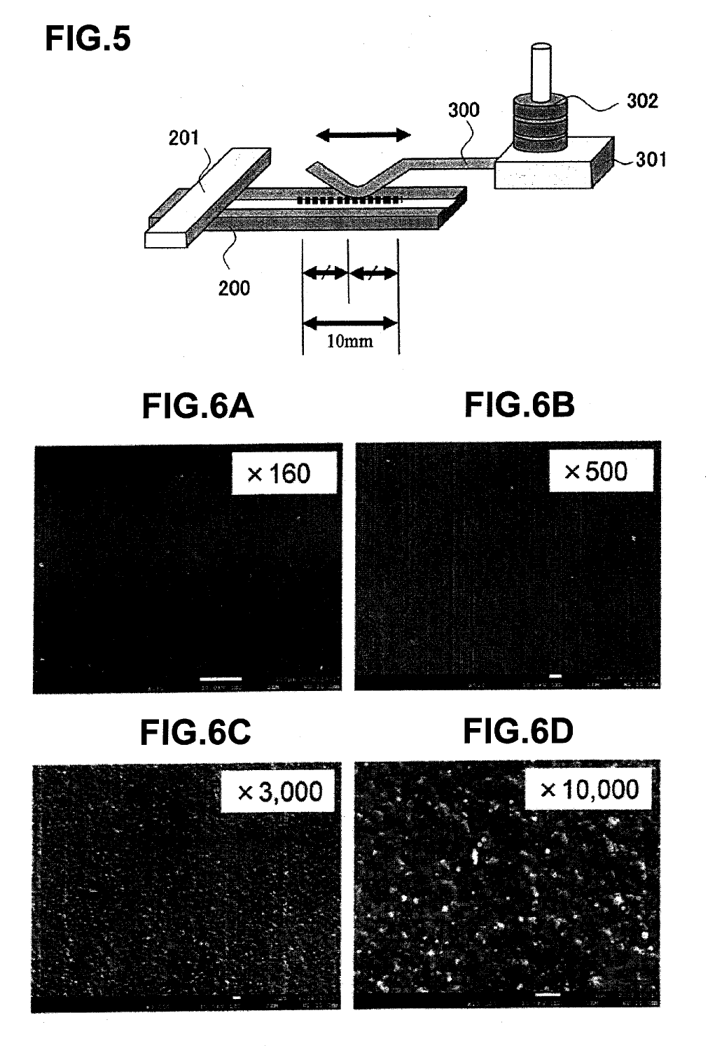

FIGS. 5A to 5D and FIGS. 6A to 6D are electron micrographs (SEM) of the surface of the AgPd alloy layer according to Example 3a in the present first example. The magnifications are 160, 500, 3,000, 10,000, 20,000, 50,000, 100,000, and 1000,000 (FIGS. 6C and 6D are the sane magnifications).

It was confirmed from FIG. 5A and FIG. 5B that an AgPd alloy layer having an almost flat surface was formed, and it was confirmed from FIG. 5D that AgPd fine particles having a size of about 100 nm were deposited.

Further, it was confirmed from FIG. 6C and FIG. 6D that the dimension of the crystal grains of the cross-sectional structure was 100 nm, and the particles of AgPd alloy which became secondary particles having a crystal grain dimension of about 100 nm due to aggregation of a plurality of primary particles of AgPd alloy having a size of 1 to 20 nm and a mean grain size of about 10 nm were deposited.

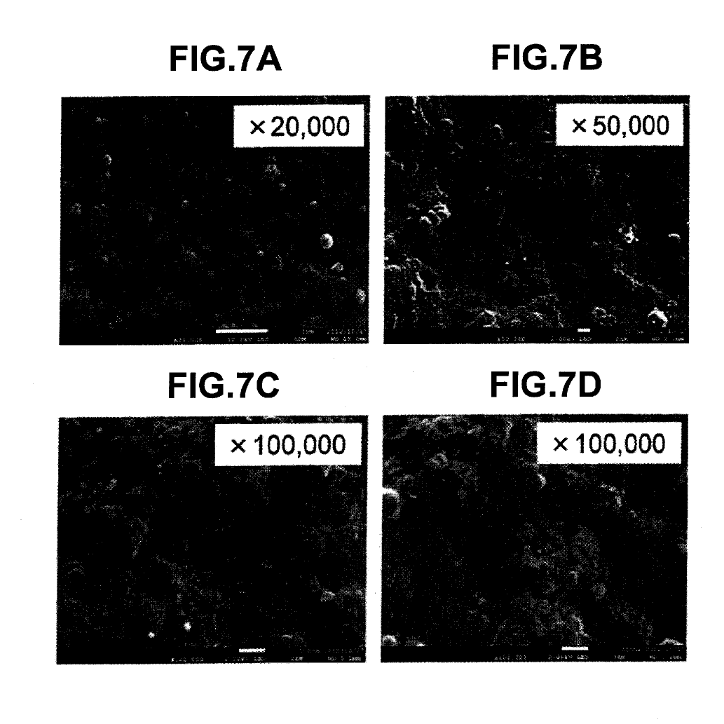

FIGS. 7A and 7B are electron micrographs (SEM) of the cross-section of the AgPd alloy layer according to Example 3a in the present first example. The magnifications are 50,000.

They show a state where an AgPd alloy layer 101 is formed on a base material 100.

Both of FIGS. 7A and 7B show that there is no clearance at the interface between the base material 100 and the AgPd alloy layer 101, so the adhesion between the base material 100 and the AgPd alloy layer 101 is good.

There are no gaps in the AgPd alloy layer 101, and it is formed as a dense film. Further, it was confirmed that there are concave portions 102 in the surface of the base material 100 in FIG. 7A, but the AgPd alloy layer was formed so as to enter the internal portions of the concave portions 102.

As described above, according to the present first example, it was confirmed that the AgPd alloy layer could be formed without problem even in a case where the shape of the base material was not flat or scratches or another concave portions existed.

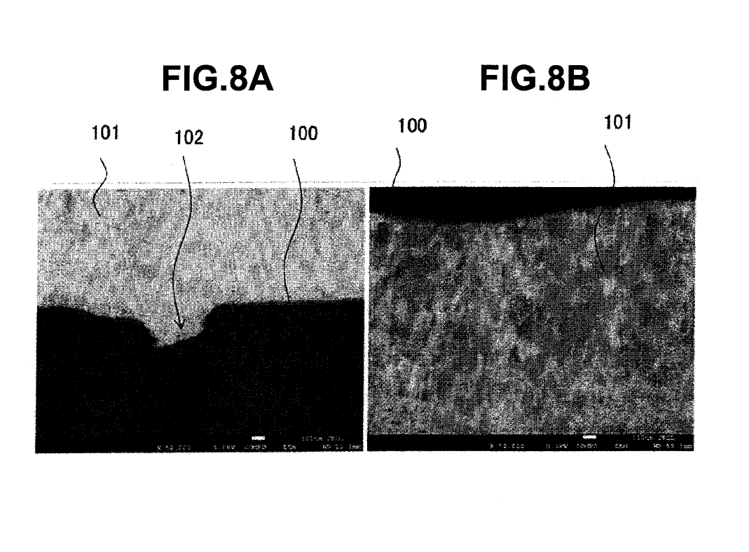

FIGS. 8A to 8C are electron micrographs (SEM) of the cross-section of the AgPd alloy layer according to Example 3a in the present first example. The magnifications are 18,000, 20,000, and 50,000.

FIG. 8A shows a state where the AgPd alloy layer 101 is formed on the base material 100 and further enlarges the regions of the AgPd alloy layer in FIGS. 8B and 8C.

It was confirmed from FIGS. 8A to 8C that AgPd fine particles having a size of about 100 nm were deposited. Further, it was confirmed that there were no coarse particles in the structure of the AgPd alloy layer, and the size of the fine particles of AgPd alloy which form the structure became uniform in the thickness direction.

The AgPd layers of Examples 1a and 2a and 4a to 6a and Comparative Example 1a were examined for cross-sections in the sane way. The dimensions of crystal grains of the cross-sectional structures of the samples and presence of coarse particles are shown in Table 1.

Further, the vacuum vapor deposition process according to the prior art was used to form an AgPd layer in the sane way, but no crystal structure could be observed.

(Peeling Test)

Even when the samples of Examples 1a to 6a and Comparative Example 1a were cut, the AgPd alloy layers did not peel off.

(Bending Test)

Even when the samples of Examples 1a to 6a and Comparative Example 1a were bent by 90° and then returned to the original state as a bending test, the AgPd alloy layers did not peel off. As described above, according to the present first example, it was confirmed that the adhesion between the base material 100 and the AgPd alloy layer 101 was good and the film was hard to peel off.

(Sliding Test)

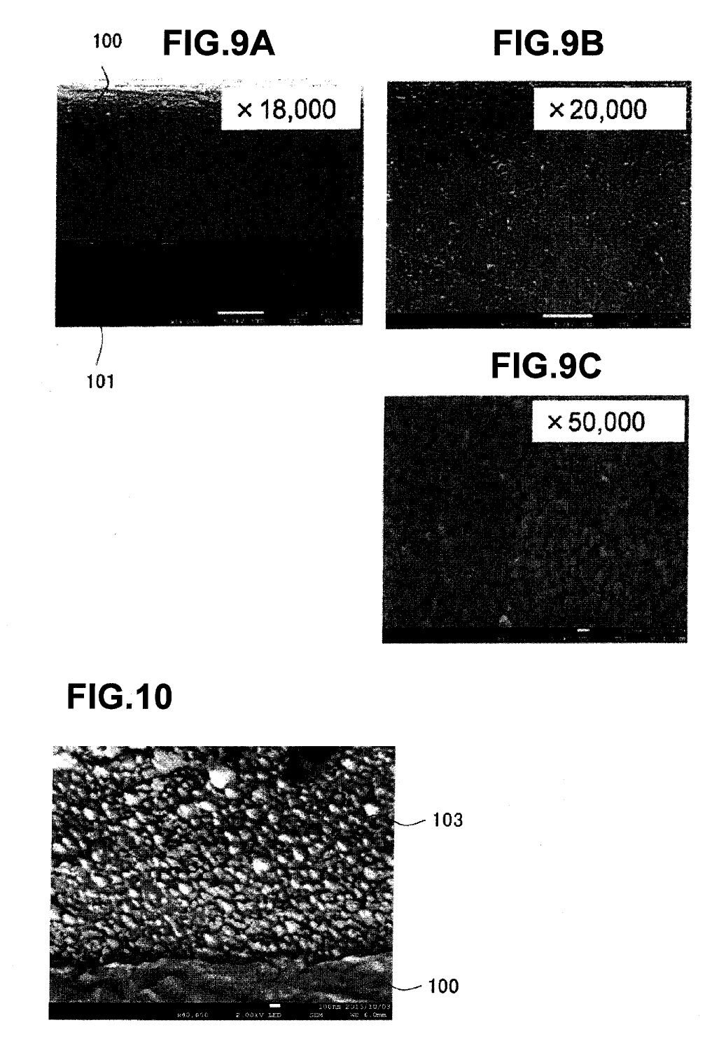

FIG. 9 is a schematic diagram of a sliding test device.

From the samples of Examples 1a to 6a and Comparative Example 1a, sliding test-use brushes (fixed side sliding contacts) 200 are formed. A commutator (movable side sliding contact) 300 is formed from AgCu4Ni0.5.

The sliding test-use commutator 300 is bent so as to facilitate contact with the sliding test-use brushes 200.

An electrode 201 is provided on the sliding test-use brush 200. Further, an electrode 301 is provided at the sliding test-use commutator 300. The sliding test-use commutator 300 is provided so that it can slide relative to the sliding test-use brush 200 in a state where a load 302 of 20 g is applied.

The sliding test-use commutator 300 slides back and forth in a region having a length of 10 nm on the sliding test-use brush 200. It slides by 20 nm in 1 cycle, so one sliding test is performed over a 1 km sliding length by 50,000 cycles.

The sliding is carried out for 1.4 seconds in 1 cycle and is stopped for 0.2 seconds at the end parts of the sliding operations. The sliding test is performed for 50,000 cycles over about 19.5 hours.

(Measurement of Abrasion Loss)

After the end of the sliding test, the abrasion losses of the sliding regions of the sliding test-use brushes were measured by a laser microscope. The loss was judged as good (“Good”) when the abrasion loss was less than 3 μm, as somewhat good (“Fair”) when it was 3 μm to less than 6 μm, and as bad (“Poor”) when it was 6 μm or more.

(Measurement of Contact Resistance)

Further, after the end of the sliding test, while sliding for 1 cycle, a current of 6V and 50 mA was run between the electrode 201 and the electrode 301, and the maximum value of the contact resistance between the sliding test-use brush and the sliding test-use commutator was measured by a milli-ohm meter. The resistance was judged as good (“Good”) when the resistance was less than 50 mΩ, as somewhat good (“Fair”) when it was 50 mΩ to less than 100 mΩ, and as bad (“Poor”) when it was 100 mΩ or more.

As shown in Table 1, in Examples 1a to 6a, the contact resistance was good, and the abrasion loss was good.

In Comparative Example 1a, the contact resistance was bad.

### Third Embodiment

### Constitution of Sliding Contact Material (AgPd Alloy Layer)

The sliding contact material in the present embodiment, in the sane way as FIG. 1 according to the first embodiment, is configured with an AgCu alloy layer formed as the Ag-containing layer on a base material.

The base material 33 is the sane as that in the first embodiment.

The AgCu alloy layer in the present embodiment is formed by irradiating the AgCu alloy by a high-energy laser beam having a spot diameter for causing vaporization from the AgCu alloy as fine particles of AgCu alloy and ejecting the fine particles of AgCu alloy which are obtained by vaporization by irradiating as jet to the base material 33 under a high vacuum atmosphere to make them physically deposit on the base material 33.

In the AgCu alloy layer, for example, the Cu can be suitably adjusted within a range of 0 to 100 wt %, therefore the degree of freedom of composition of the formable AgCu alloy is large. The invention can be applied also to Pg alone with Cu: 0 wt % or to Cu alone with Cu: 100 wt %.

Further, the film thickness of the AgCu alloy layer is for example 0.05 to 22 μm, preferably 1 to 10 μm.

The AgCu alloy layer of the sliding contact material in the present embodiment is formed by for example depositing fine particles of AgCu alloy having a size of 1 to 200 nm. The fine particles of AgCu alloy are deposited with a uniform size in the thickness direction of the AgCu alloy layer 1.

Alternatively, the AgCu alloy layer of the sliding contact material in the present embodiment is formed by for example depositing fine particles of AgCu alloy which become secondary particles due to aggregation of a plurality of primary particles of AgCu alloy having a size of 1 to 20 nm. The fine particles of AgCu alloy are deposited with a uniform size in the thickness direction of the AgCu alloy layer.

This is the sane as the first embodiment except for the above description.

The base material on which the above AgCu alloy layer is formed is worked to for example a brush shape and can be applied to a sliding contact material which is used in a mechanical sliding portion of a DC small-sized motor, position sensor, or other rotating device as a brush.

Further, the sliding contact material (AgCu alloy layer) according to the present embodiment can be produced by for example a physical vapor deposition process using the sane physical vapor deposition apparatus as those in the first embodiment and second embodiment wherein the vaporization source is made an AgCu alloy.

The film thickness of the AgCu alloy layer formed in the present embodiment is for example 0.05 to 22 μm, preferably 1 to 10 μm.

According to the method of producing the sliding contact material in the present embodiment, there are the advantages that, even when the film thickness of the AgCu alloy layer is increased up to for example about 5 to 22 μm, the internal strain is small, cracking at the time of film formation can be suppressed, and therefore the degree of freedom of film thickness is large.

The AgCu alloy layer which is formed in the method of producing the sliding contact material in the present embodiment has a high adhesion with the base material. Therefore, even when it is used in a rotating device and is made to slide, peeling of the AgCu alloy layer can be suppressed.

In the method of producing the sliding contact material in the present embodiment, for example, the AgCu alloy layer can be formed by depositing fine particles of AgCu alloy having a size of 1 to 200 nm with a uniform size in the thickness direction of the AgCu alloy layer.

Alternatively, for example, the AgCu alloy layer can be formed by depositing fine particles of AgCu alloy which become secondary particles by aggregation of a plurality of primary particles of AgCu alloy having a size of 1 to 200 nm with a uniform size in the thickness direction of the AgCu alloy layer.

According to the method of producing the sliding contact material in the present embodiment, the cladding composite material which is obtained by coating the surface of the base material with the AgCu alloy layer forming the sliding contact material can be formed so that the size of the fine particles of AgCu alloy which form the structure of the AgCu alloy layer becomes uniform in the thickness direction.

Accordingly, peeling of coarse particles at the time of abrasion of the sliding contact material is prevented, therefore the contact resistance at the time of sliding of the sliding contact material is good, the abrasion loss is small, and poor contact in the contact parts and variation of lifespan of the rotating device can be suppressed.

### Second Example

According to the method of producing the sliding contact material according to the third embodiment, AgCu alloy layers having compositions shown in Table 2 were formed with a film thickness of 6 μm on base materials comprised of CuSn alloy to thereby prepare Examples 1b to 6b.

Further, a cladding method according to the prior art was used to form an AgCu alloy layer on a substrate to a film thickness of 6 μm to prepare Comparative Example 1b.

TABLE 2

| | | | Dimension of | | | |
|---|---|---|---|---|---|---|
| | | | crystal grains | | | |
| | | | of | Presence | Sliding test | |
| | Composition | | cross-sectional | of | Contact | Abra- |
| | (wt %) | | structure | coarse | resis- | sion |
| | Ag | Cu | (nm) | particles | tance | loss |
| Example 1b | 85 | 15 | 20 | No | Good | Good |
| Example 2b | 85 | 15 | 50 | No | Good | Good |
| Example 3b | 85 | 15 | 100 | No | Good | Good |
| Example 4b | 85 | 15 | 180 | No | Good | Good |
| Example 5b | 90 | 10 | 140 | No | Good | Good |
| Example 6b | 70 | 30 | 30 | No | Good | Good |
| Comparative | 85 | 15 | 2000 | Yes | Poor | Fair |
| Example 1b | | | | | | |

Examples 1b to 6b were examined by electron micrographs (SEM). As a result, it was confirmed that the surface states of the AgCu alloy layers were the sane as those in the first example and that AgCu alloy layers having substantially flat surfaces were formed.

FIG. 10 is an electron micrograph (SEM) of the cross-section of the AgCu alloy layer according to Example 3b. The magnification is 50,000.

FIG. 10 shows a state where an AgCu alloy layer 103 is formed on a base material 100.

It was confirmed from FIG. 10 that the dimension of the crystal grains in the cross-sectional structure was about 100 nm and that particles of AgCu alloy which became secondary particles having a crystal grain dimension of about 100 nm due to aggregation of a plurality of primary particles of AgCu alloy having a size of 1 to 20 nm were deposited.

Further, it was confirmed that there were no coarse particles in the structure of the AgCu alloy layer and that the size of the fine particles of the AgCu alloy which form the structure became uniform in the thickness direction.

The AgCu layers of Examples 1b and 2b and 4b to 6b were examined for cross-sections in the sane way. The dimensions of crystal grains in the cross-sectional structures of the samples and the presences of coarse particles are shown in Table 2.

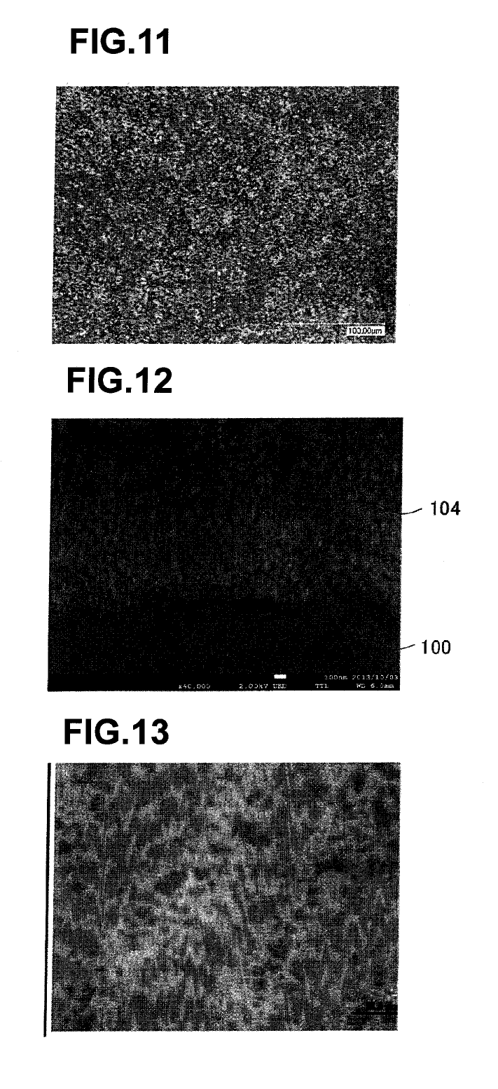

FIG. 11 is an electron micrograph of the surface of the AgCu alloy layer according to Comparative Example 1b. The magnification is 1,000.

In Comparative Example 1b, coarse particles were observed in the structure of the AgCu alloy layer.

Further, the vacuum vapor deposition process according to the prior art was used to form the AgCu alloy layer in the sane way, but no crystal structure could be observed.

(Peeling Test)

Examples 1b to 6b and Comparative Example 1b were tested by a peeling test the same as that for the first example.

The AgCu alloy layers in Examples 1b to 6b did not peel off.

(Bending Test)

Examples 1b to 6b and Comparative Example 1b were tested by a bending test the same as that for the first example.

The AgCu alloy layers in Examples 1b to 6b did not peel off.

As described above, according to Examples 1b to 6b, it was confirmed that the adhesion between the base material and the AgCu alloy layer was good, and the film was hard to peel off.

(Sliding Test)

Examples 1b to 6b and Comparative Example 1b were tested by a sliding test and measured for abrasion loss and contact resistance in the same way as the first example.

As shown in Table 2, in Examples 1b to 6b, the contact resistance was good, and the abrasion loss was good. In Comparative Example 1b, the contact resistance was bad.

### Fourth Embodiment

### Constitution of Sliding Contact Material (AgNi Alloy Layer)

The sliding contact material in the present embodiment, in the same way as FIG. 1 according to the first embodiment, is configured with an AgNi alloy layer formed as the Ag-containing layer on a base material.

The base material 33 is the sane as that in the first embodiment.

The AgNi alloy layer in the present embodiment is formed by irradiating the vaporization source which contains Ag and Ni by a high-energy laser beam having a spot diameter for causing vaporization from a vaporization source which contains Ag and Ni as fine particles of AgNi alloy and ejecting the fine particles of AgNi alloy which are obtained by vaporization by irradiating as jet to the base material under a high vacuum atmosphere to make them physically deposit on the base material 33.

In Ag, only about 0.01 to 0.02% of Ni can be dissolved. Therefore, in a case where an AgNi alloy layer having an Ni content exceeding that is to be formed, usually powder metallurgy processing is used. In this case, as the material for film formation, powder state Ni particles are mixed during the production. However, the size of particles constituting an AgNi alloy layer is determined according to the size of the powder state Ni particles.

In order to make the particles which constitute the AgNi alloy layer small, it is necessary to make the powder state Ni particles to be mixed small. However, in powder metallurgy, it was very difficult to form an AgNi alloy layer comprised of fine particles.

While only about 0.01 to 0.02% of Ni can be dissolved in Ag, in the AgNi alloy layer in the present embodiment, for example, Ni can be suitably adjusted within a range of 0 to 100 wt %. The invention can be particularly preferably applied to a range where Ni is 5 to 30 wt %, therefore the degree of freedom of the composition of the AgNi alloy which can be formed is large.

Further, the film thickness of the AgNi alloy layer 1 is for example 0.05 to 22 μm, preferably 1 to 10 μm.

The AgNi alloy layer of the sliding contact material in the present embodiment is formed by for example depositing fine particles of AgNi alloy having a size of 1 to 200 nm. The fine particles of AgNi alloy are deposited with a uniform size in the thickness direction of the AgNi alloy layer 1.

Alternatively, the AgNi alloy layer of the sliding contact material in the present embodiment is formed by for example depositing fine particles of AgNi alloy which become secondary particles due to aggregation of a plurality of primary particles of AgNi alloy having a size of 1 to 20 nm. The fine particles of AgNi alloy are deposited with a uniform size in the thickness direction of the AgNi alloy layer.

This is the sane as the first embodiment except for the above description.

The base material on which the above AgNi alloy layer is formed is worked to for example a brush shape and can be applied to a sliding contact material which is used in a mechanical sliding portion of a DC small-sized motor, position sensor, or other rotating device as a brush.

Further, the sliding contact material (AgNi alloy layer) according to the present embodiment can be produced by for example a physical vapor deposition process using the sane physical vapor deposition apparatus as those in the first embodiment and second embodiment wherein the vaporization source is made a vaporization source which contains Ag and Ni.

The film thickness of the AgNi alloy layer 1 which is formed in the present embodiment is for example 0.05 to 22 μm, preferably 1 to 10 μm.

According to the method of producing the sliding contact material in the present embodiment, there are the advantages that even when the film thickness of the AgNi alloy layer is enlarged up to for example about 5 to 22 μm, the internal strain is small and cracking at the time of film formation can be suppressed, so the degree of freedom of the film thickness is large.

The AgNi alloy layer which is formed in the method of producing the sliding contact material in the present embodiment has a high adhesion with the base material, therefore peeling of the AgNi alloy layer can be suppressed even when it is used in a rotating device and is made to slide.

In the method of producing the sliding contact material in the present embodiment, for example, the AgNi alloy layer can be formed by depositing fine particles of AgNi alloy having a size of 1 to 200 nm with a uniform grain size in the thickness direction of the AgNi alloy layer.

Alternatively, the AgNi alloy layer can be formed by for example a plurality of primary particles of AgNi alloy having a size of 1 to 200 nm being aggregated to form secondary particles, and the thus obtained fine particles of AgNi alloy are deposited with a uniform grain size in the thickness direction of the AgNi alloy layer.

According to the method of producing the sliding contact material in the present embodiment, the cladding composite material which is obtained by coating the surface of the base material with an AgNi alloy layer for forming the sliding contact material can be formed so that the size of the fine particles of the AgNi alloy which form the structure of the AgNi alloy layer becomes uniform in the thickness direction.

Accordingly, peeling of coarse particles at the time of abrasion of the sliding contact material is prevented, the contact resistance at the time of sliding of the sliding contact material is good, and the abrasion loss is small, therefore poor contact in the contact parts and variation of lifespan as the rotating device can be suppressed.

### Third Embodiment

According to the method of producing the sliding contact material according to a fourth embodiment, AgNi alloy layers having compositions shown in Table 3 were formed with a film thickness of 6 μm on base materials comprised of CuSn alloy to thereby prepare Examples 1c to 6c.

Further, a cladding method according to the prior art was used to form an AgNi alloy layer on a substrate to a film thickness of 6 μm to prepare Comparative Example 1c.

TABLE 3

| | | | Dimension | | | |
|---|---|---|---|---|---|---|
| | | | of crystal | | | |
| | | | grains of | Presence | Sliding test | |
| | Composition | | sectional | of | Contact | Abra- |
| | (wt %) | | structure | coarse | resis- | sion |
| | Ag | Ni | (nm) | particles | tance | loss |
| Example 1c | 90 | 10 | 20 | No | Good | Good |
| Example 2c | 90 | 10 | 40 | No | Good | Good |
| Example 3c | 90 | 10 | 120 | No | Good | Good |
| Example 4c | 90 | 10 | 190 | No | Good | Good |
| Example 5c | 95 | 5 | 180 | No | Good | Good |
| Example 6c | 70 | 30 | 40 | No | Good | Good |
| Comparative | 90 | 10 | 10000 | Yes | Poor | Fair |
| Example 1c | | | | | | |

Examples 1c to 6c were examined by electron micrographs (SEM). As a result, it was confirmed that the surface states of the AgNi alloy layers were the sane as those in the first example and that AgNi alloy layers having substantially flat surfaces were formed.

FIG. 12 is an electron micrograph (SEM) of the cross-section of the AgNi alloy layer according to Example 3c. The magnification is 40,000.

FIG. 12 shows a state where an AgNi alloy layer 104 is formed on a base material 100.

It was confirmed from FIG. 12 that the dimension of the crystal grains in the cross-sectional structure was about 120 nm and that particles of AgNi alloy which became secondary particles having a crystal grain dimension of about 120 nm due to aggregation of a plurality of primary particles of AgNi alloy having a size of 1 to 20 nm were deposited.

Further, it was confirmed that there were no coarse particles in the structure of the AgNi alloy layer and that the size of the fine particles of the AgNi alloy which form the structure became uniform in the thickness direction.

The AgNi layers of Examples 1c and 2c and 4c to 6c were examined for cross-sections in the sane way. The dimensions of crystal grains in the cross-sectional structures of the samples and the presences of coarse particles are shown in Table 3.

FIG. 13 is an electron micrograph of the surface of the AgNi alloy layer according to Comparative Example 1c. The magnification is 1,000.

In Comparative Example 1c, coarse particles were observed in the structure of the AgNi alloy layer.

Further, the vacuum vapor deposition process according to the prior art was used to form an AgNi alloy layer in the someway, but no crystal structure could be observed.

(Peeling Test)

Examples 1c to 6c and Comparative Example 1c were tested by the same peeling test as that for the first example. The AgNi alloy layers in Examples 1c to 6c did not peel off.

(Bending Test)

Examples 1c to 6c and Comparative Example 1c were tested by the same bending test as that for the first example.

The AgNi alloy layers in Examples 1c to 6c did not peel off.

As described above, according to Examples 1c to 6c, it was confirmed that the adhesion between the base material and the AgNi alloy layer was good and the film was hard to peel off.

(Sliding Test)

Examples 1c to 6c and Comparative Example 1c were tested by a sliding test and the abrasion loss and contact resistance were measured in the same way as the first example.

As shown in Table 3, in Examples 1c to 6c, the contact resistance was good and the abrasion loss was good.

In Comparative Example 1c, the contact resistance was bad.

### Fifth Embodiment

### Constitution of Sliding Contact Material (Ag-Nonmetal Composite Layer)

The sliding contact material in the present embodiment, in the same way as FIG. 1 according to the first embodiment, is configured with an Ag-nonmetal composite layer formed as the Ag-containing layer on a base material.

The base material is the same as that in the first embodiment.

The Ag-nonmetal composite layer in the present embodiment is for example a composite layer of Ag with ZnO, SnO, InO, or another oxide, WC or another carbide, or another nonmetal. The Ag-nonmetal composite layer can be also applied to a composite layer comprised of Ag and an oxide or carbide other than those described above.

For example, this is formed by irradiating a vaporization source of the composite material of Ag and ZnO by a high-energy laser beam having a spot diameter for causing vaporization from the vaporization source of the composite material of Ag and ZnO as fine particles of the composite material of Ag and ZnO, and ejecting fine particles of the composite material of Ag and ZnO which are obtained by vaporization by irradiating as jet to the base material under a high vacuum atmosphere to physically deposit than on the base material.

An Ag-nonmetal composite layer comprised of another material is formed by using a vaporization source of a corresponding Ag-nonmetal composite material.

In the prior art, in a material obtained by dispersing ceramic or superhard alloy in Ag, working the material becomes difficult if the amount of ceramic or superhard alloy becomes large. Therefore, it becomes difficult to disperse and mix it over a constant amount. Further, the size of that ceramic or superhard alloy depends upon the initial size of the ceramic or superhard alloy which is supplied at the time of film formation, therefore reduction of size to a constant size or less is difficult.

The Ag-nonmetal composite layer in the present embodiment can be suitably adjusted within a range of for example 0 to 100 wt % of nonmetal, therefore the degree of freedom of the composition of the Ag-nonmetal composite layer is large.

Further, the film thickness of the Ag-nonmetal composite layer is for example 0.05 to 22 μm, preferably 1 to 10 μm.

The Ag-nonmetal composite layer of the sliding contact material in the present embodiment is formed by for example depositing Ag-nonmetal composite fine particles having a size of 1 to 200 nm. The Ag-nonmetal composite fine particles are deposited with a uniform size in the thickness direction of the Ag-nonmetal composite layer.

Alternatively, the Ag-nonmetal composite layer of the sliding contact material in the present embodiment is formed by for example depositing fine particles of an Ag-nonmetal composite which become secondary particles due to aggregation of a plurality of primary particles of Ag having a size of 1 to 20 nm and a plurality of primary particles of nonmetal such as ZnO. The Ag-nonmetal composite fine particles are deposited with a uniform size in the thickness direction of the Ag-nonmetal composite layer.

This is the sane as the first embodiment except for the above description.

The base material on which the above Ag-nonmetal composite layer is formed is worked to for example a brush shape and can be applied to a sliding contact material which is used in a mechanical sliding portion of a DC small-sized motor, position sensor, or other rotating device as a brush.

Further, the sliding contact material (Ag-nonmetal composite layer) according to the present embodiment can be produced by for example a physical vapor deposition process using the sane physical vapor deposition apparatus as those in the first embodiment and second embodiment wherein the vaporization source is made a vaporization source of the Ag-nonmetal composite material.

The film thickness of the Ag-nonmetal composite layer formed in the present embodiment is for example 0.05 to 22 μm, preferably 1 to 10 μm.

According to the method of producing the sliding contact material in the present embodiment, there are the advantages that even if the film thickness of the Ag-nonmetal composite layer is increased up to for example about 5 to 22 μm, the internal strain is small, cracking at the time of the film formation can be suppressed, and therefore the degree of freedom of the film thickness is large.

The Ag-nonmetal composite layer which is formed in the method of producing the sliding contact material in the present embodiment has a high adhesion with the base material, therefore even when it is used in the rotating device and is made to slide, peeling of the Ag-nonmetal composite layer can be suppressed.

In the method of producing the sliding contact material in the present embodiment, for example, the Ag-nonmetal composite layer can be formed by depositing Ag-nonmetal composite fine particles having a size of 1 to 200 nm with a uniform size in the thickness direction of the Ag-nonmetal composite layer.

Alternatively, for example, the Ag-nonmetal composite layer can be formed by depositing fine particles of an Ag-nonmetal composite which become secondary particles due to aggregation of a plurality of primary particles of Ag having a size of 1 to 200 nm and a plurality of primary particles of nonmetal with a uniform size in the thickness direction of the Ag-nonmetal composite layer.

According to the method of producing the sliding contact material in the present embodiment, the cladding composite material which is obtained by coating the surface of the base material with an Ag-nonmetal composite layer for forming the sliding contact material can be formed so that the size of the Ag-nonmetal fine particles which form the structure of the Ag-nonmetal layer becomes uniform in the thickness direction.

Accordingly, peeling of coarse particles at the time of abrasion of the sliding contact material is prevented, the contact resistance at the time of sliding of the sliding contact material is good, and the abrasion loss is small, therefore poor contact in the contact parts and variation of lifespan as the rotating device can be suppressed.

### Fourth Example

According to the method of producing the sliding contact material according to a fifth embodiment, on base materials comprised of CuSn alloy, composite layers of Ag and nonmetal (ZnO, SnO, InO, or WC) having compositions shown in Table 4 were formed with a film thickness of 6 μm to thereby prepare Examples 1d to 7d. For example, Example 1d is a composite film which was formed by using a vaporization source of a composite material which contains Ag: 91 wt % and ZnO: 9 wt %. Examples 2d to 7d are the same as well.

Further, a cladding method according to the prior art was used to form composite layers of Ag and nonmetal (ZnO or WC) shown in Table 4 on substrates to a film thickness of 6 μm to prepare Comparative Examples 1d and 2d.

TABLE 4

| | | | Dimension | | | |
|---|---|---|---|---|---|---|
| | | | of crystal | | | |
| | Composition | | grains of | Presence | Sliding test | |
| | (wt %) | | cross-sectional | of | Contact | Abra- |
| | | Non- | structure | coarse | resis- | sion |
| | Ag | metal | (nm) | particles | tance | loss |
| Example 1d | 9 | ZnO: 9% | 20 | No | Good | Good |
| | 1 | | | | | |
| Example 2d | 9 | ZnO: 9% | 50 | No | Good | Good |
| | 1 | | | | | |
| Example 3d | 9 | ZnO: 9% | 110 | No | Good | Good |
| | 1 | | | | | |
| Example 4d | 9 | ZnO: 9% | 190 | No | Good | Good |
| | 1 | | | | | |
| Example 5d | 9 | SnO: 9% | 150 | No | Good | Good |
| | 0 | | | | | |
| Example 6d | 9 | InO: 10% | 100 | No | Good | Good |
| | 0 | | | | | |
| Example 7d | 9 | WC: 10% | 80 | No | Good | Good |
| | 0 | | | | | |
| Comparative | 9 | ZnO: 9% | 1100 | Yes | Poor | Poor |
| Example 1d | 1 | | | | | |
| Comparative | 9 | WC: 10% | 1000 | Yes | Poor | Poor |
| Example 2d | 0 | | | | | |

Examples 1d to 7d were examined by electron micrographs (SEM). As a result, it was confirmed that the surface states of the Ag-nonmetal composite layers were the sane as those in the first example and that Ag-nonmetal composite layers having substantially flat surfaces were formed.

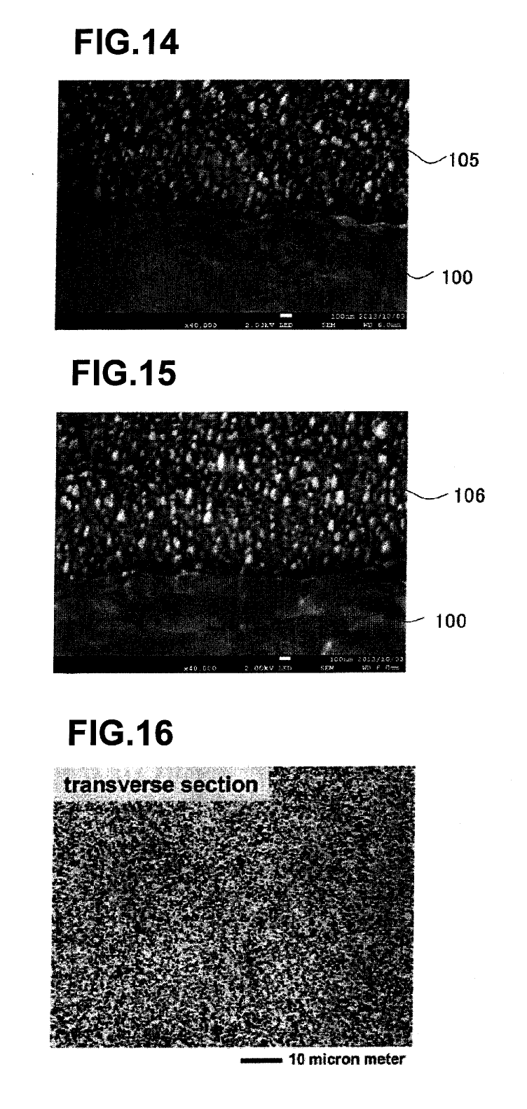

FIG. 14 and FIG. 15 are electron micrographs (SEM) of the cross-sections of the composite layer of Ag and nonmetal (ZnO) according to Example 3d and composite layer of Ag and nonmetal (WC) according to Example 7d. The magnifications are 40,000.

FIG. 14 shows a state where a composite layer 105 of Ag and nonmetal (ZnO) is formed on a base material 100.

FIG. 15 shows a state where a composite layer 106 of Ag and nonmetal (WC) is formed on a base material 100.

It was confirmed from FIG. 14 that the dimension of the crystal grains in the cross-sectional structure was about 110 nm, and composite particles of about 110 nm due to aggregation of a plurality of primary particles of Ag having a size of 1 to 20 nm and a plurality of primary particles of nonmetal (ZnO) having the sane size were deposited. Further, it was confirmed from FIG. 15 that the dimension of the crystal grains in the cross-sectional structure was about 80 nm, and composite particles of about 80 nm due to aggregation of a plurality of primary particles of Ag having a size of 1 to 20 nm and a plurality of primary particles of nonmetal (WC) having the sane size were deposited.

Further, it was confirmed that there were no coarse particles in the structure of the Ag-nonmetal composite layer and the size of the Ag-nonmetal composite fine particles constituting the structure became uniform in the thickness direction.

The Ag-nonmetal composite layers of Examples 1d to 2d and 4d to 6d were examined for cross-sections in the sane way. The dimensions of the crystal grains of the cross-sectional structures of the samples and presence of coarse particles are shown in Table 4.

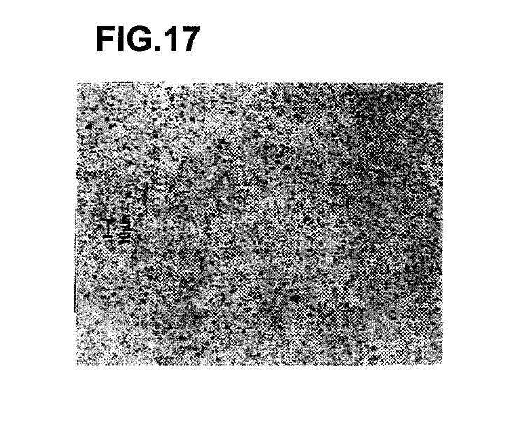

FIG. 16 and FIG. 17 are electron micrographs of the surfaces of the Ag-nonmetal composite layers according to Comparative Example 1d and Comparative Example 2d. The magnifications are 1,000.

In Comparative Example 1d and Comparative Example 2d, coarse particles were observed in the structures of the Ag-nonmetal composite layers.

Further, the vacuum vapor deposition process according to the prior art was used to form an Ag-nonmetal composite layer in the sane way, but no crystal structure could be observed.

(Bending Test)

Examples 1d to 7d and Comparative Examples 1d and 2d were tested by a bending test the sane as that for the first embodiment.

The Ag-nonmetal composite layers in Examples 1d to 7d did not peel off.

As described above, according to Examples 1d to 7d, it was confirmed that the adhesion between the base material and the Ag-nonmetal composite layer was good, and the film was hard to peel off.

(Sliding Test)

Examples 1d to 7d and Comparative Examples 1d and 2d were tested by a sliding test and measured for abrasion loss and contact resistance in the sane way as the first Embodiment.

As shown in Table 4, in Examples 1d to 7d, the contact resistance was good, and the abrasion loss was good.

In Comparative Examples 1d and 2d, both of the contact resistance and the abrasion loss were bad.

The present invention is not limited to the above explanation.

For example, the velocity of the gas stream which is obtained by ejecting the gas which contains the fine particles of AgPd alloy, fine particles of AgCu alloy, fine particles of AgNi alloy, or Ag-nonmetal composite fine particles from a nozzle is not limited to a supersonic speed and may be subsonic or transonic as well.

As the AgPd alloy, other than an AgPdCu alloy, PtAuAgPdCuZn alloy, or other alloy, the present invention can be also applied to a multicomponent alloy which contains AgPd as the principal component.

Further, for the AgCu alloy layer, the present invention can be applied to a multicomponent alloy which contains an AgCu alloy as the principal component. For an AgNi alloy layer, the present invention can be applied to a multicomponent alloy which contains an AgNi alloy as the principal component. For an Ag-nonmetal composite layer, the present invention can be applied to a multicomponent alloy which contains an Ag-nonmetal composite material as the principal component.

For the base material, the explanation was given of use of Cu or a Cu alloy, but the base material is not limited to this. The present invention can be applied to a base material comprised of another material as well.

Other than the above, various modifications are possible within a range not out of the gist of the present invention.

### REFERENCE SIGNS LIST

1 . . . AgPd alloy layer
10, 10A . . . vaporization chambers
10w . . . light incident window
11 . . . exhaust pipe
12 . . . mass flow control
13 . . . gas supply source
14 . . . table
14a . . . rotary motor
15 . . . vaporization source
16a . . . laser source
16b . . . aperture
16c . . . mirror
16d . . . lens
16e . . . mirror
17 . . . laser beam
18, 18A . . . transfer tubes
20 . . . control device
30, 30A . . . film-forming chambers
31 . . . exhaust pipe
32 . . . stage
33, 33A . . . base materials
33B . . . unwinding roll
33C . . . winding roll
35 . . . nozzle
36A, 36B, 37A, 37B . . . conveyor rolls
J . . . gas stream
VP1, VP3 . . . vacuum pumps

1. A method for producing an Ag-containing layer comprising:
a vaporization step of irradiating a vaporization source which contains Ag by a high-energy laser beam having a spot diameter for causing vaporization as fine particles which contain Ag from the vaporization source which contains Ag and vaporizing the fine particles which contain Ag and
a vapor deposition step of ejecting the fine particles which contain Ag which were obtained by vaporization as jet to a base material under a high vacuum atmosphere to make them physically deposit on the base material.

2. The method for producing the Ag-containing layer according to claim 1, wherein
in the vaporization step a gas which contains the fine particles which contain Ag is ejected as jet on a gas stream from a nozzle and thereby physically deposit the fine particles which contain Ag on the base material.

3. The method for producing the Ag-containing layer according to claim 2, wherein
in the vaporization step the gas stream is a supersonic, transonic, or subsonic gas stream.

4. The method for producing the Ag-containing layer according to claim 1, wherein
in the vaporization step a laser beam of a fundamental harmonic of a YAG laser, CO2 laser, or excimer laser or a laser beam having a small wavelength which is obtained by wavelength conversion of the fundamental harmonic is irradiated.

5. The method for producing the Ag-containing layer according to claim 1, wherein
the base material is Cu or a Cu alloy.

6. The method for producing the Ag-containing layer according to claim 1, wherein
the fine particles which contain Ag are AgPd fine particles, and an AgPd alloy layer is produced as the Ag-containing layer.

7. The method for producing the Ag-containing layer according to claim 1, wherein
the fine particles which contain Ag are AgCu fine particles, and an AgCu alloy layer is produced as the Ag-containing layer.

8. The method for producing the Ag-containing layer according to claim 1, wherein
the fine particles which contain Ag are AgNi fine particles, and an AgNi alloy layer is produced as the Ag-containing layer.

9. The method for producing the Ag-containing layer according to claim 1, wherein
the fine particles which contain Ag are Ag-nonmetal composite fine particles, and an Ag-nonmetal composite layer is produced as the Ag-containing layer.

10. The method for producing the Ag-containing layer as set forth in claim 9, wherein
the Ag-nonmetal composite fine particles are composite fine particles of Ag and an oxide or carbide, and a composite layer of Ag and an oxide or carbide is produced as the Ag-containing layer.

11. An apparatus for producing an Ag-containing layer comprising:
a laser source for irradiating a high-energy laser beam having a spot diameter for causing vaporization from a vaporization source which contains Ag as fine particles which contain Ag,
a vaporization chamber for irradiating the vaporization source which contains Ag by the laser beam and vaporizing fine particles which contain Ag,
a transfer tube for transferring the fine particles which contain Ag, and
a film-forming chamber for ejecting the fine particles as jet which contain Ag from a nozzle arranged on a front end of the transfer tube to the base material under a high vacuum atmosphere and making them physically deposit on the base material.

12. An Ag-containing layer which is formed by irradiating a vaporization source which contains Ag by a high-energy laser beam having a spot diameter for causing vaporization from the vaporization source which contains Ag as fine particles which contain Ag, and ejecting the fine particles which contain Ag which were obtained by vaporization by irradiating as jet to a base material under a high vacuum atmosphere to make them physically deposit on the base material.

13. An Ag-containing layer which is formed by depositing 1 to 200 nm size fine particles which contain Ag with a uniform size in the thickness direction on a base material.

14. A sliding contact material comprising:
a base material and
an Ag-containing layer which is formed by irradiating a vaporization source which contains Ag by a high-energy laser beam having a spot diameter for causing vaporization from the vaporization source which contains Ag as fine particles which contain Ag, and ejecting the fine particles which contain Ag which were obtained by vaporization by irradiating as jet to a base material under a high vacuum atmosphere to make them physically deposit on the base material.

15. A sliding contact material comprising:
a base material and
an Ag-containing layer which is formed by depositing 1 to 200 nm size fine particles which contain Ag with a uniform size in the thickness direction on the base material.

16. The method for producing the Ag-containing layer according to claim 2, wherein
in the vaporization step a laser beam of a fundamental harmonic of a YAG laser, CO2 laser, or excimer laser or a laser beam having a small wavelength which is obtained by wavelength conversion of the fundamental harmonic is irradiated.

17. The method for producing the Ag-containing layer according to claim 2, wherein
the base material is Cu or a Cu alloy.

18. The method for producing the Ag-containing layer according to claim 2, wherein
the fine particles which contain Ag are AgPd fine particles, and an AgPd alloy layer is produced as the Ag-containing layer.

19. The method for producing the Ag-containing layer according to claim 2, wherein
the fine particles which contain Ag are AgCu fine particles, and an AgCu alloy layer is produced as the Ag-containing layer.

20. The method for producing the Ag-containing layer according to claim 2, wherein
the fine particles which contain Ag are AgNi fine particles, and an AgNi alloy layer is produced as the Ag-containing layer.
